(19) United States
(12) Patent Application Publication
(10) Pub. No.: US 2025/0069842 A1
(43) Pub. Date: Feb. 27, 2025

(54) TECHNIQUES FOR WAVEFORM DETECTION OF PERIODIC SIGNALS USING VOLTAGE CONTRAST

(71) Applicant: FEI Company, Hillsboro, OR (US)

(72) Inventors: Neel Leslie, San Jose, CA (US); James Vickers, San Jose, CA (US)

(21) Appl. No.: 18/456,263

(22) Filed: Aug. 25, 2023

(51) Int. Cl. H01J 37/22; G01R 31/26; H01J 37/04

(52) U.S. Cl. CPC H01J 37/222; G01R 31/2603; H01J 37/045; H01J 2237/2817

(57) ABSTRACT

Systems, components, computer-implemented methods, and algorithms for generating waveform data are described. A method for generating waveform data can include directing a pulsed beam of charged particles toward a sample. The sample can include a conductive feature to which a transient electrical signal is applied. The pulsed beam of charged particles can be characterized by a pulse period measured in units of time. The method can include generating detector data over a period of time corresponding to a multiple of the pulse period. The detector data can be generated based at least in part on interactions between the charged particles and the sample. The method can also include generating waveform data describing the transient electrical signal using the detector data.

### TECHNICAL FIELD

Embodiments of the present disclosure are directed to electronic testing systems, as well as algorithms and methods for their operation. In particular, some embodiments are directed toward techniques for integrated circuit testing.

### BACKGROUND

Integrated circuit (IC) testing involves measurement of individual transistors or groups of transistors of a semiconductor wafer or wafer section (e.g., a diced wafer), termed a “device under test” or DUT. A typical IC testing regime includes applying a periodic signal to a circuit at increasingly higher power, as an approach to examining circuit performance under different operating conditions and to determine at what point the circuit fails to operate to specifications. To that end, IC testing also includes measuring output signals from IC components for comparison of measured outputs to expected outputs.

Measurements of output signals are complicated by several factors. For example, an IC may contain billions of transistors and billions of internal signal nets, yet may only possesses hundreds of input/output pins. Hence, when an output signal from an IC component under test fails to match its expected output, internal signals within the IC can be probed to identify local contributions to the output signal failure. There is a need, therefore, for techniques that permit sampling of internal and output signals within a DUT during testing, in a fashion that is intuitive for visual inspection, for example, during troubleshooting, while also protecting IC components from degradation and that improve signal-to-noise as duty cycle deviates from nominal conditions during an IC test.

### BRIEF SUMMARY

Systems, components, computer-implemented methods, and algorithms for generating waveform data are described. In an aspect, a method for generating waveform data includes directing a pulsed beam of charged particles toward a sample. The sample can include a conductive feature to which a transient electrical signal is applied. The pulsed beam of charged particles can be characterized by a pulse period measured in units of time. The method can include generating detector data over a period of time corresponding to a multiple of the pulse period. The detector data can be generated based at least in part on interactions between the charged particles and the sample. The method can also include generating waveform data describing the transient electrical signal using the detector data.

In some embodiments, the transient signal is a periodic electrical signal. A value “P” can be a period of the transient signal, measured in units of time. The pulse period can differ from an integer multiple of P, N*P, by an increment, dP. The method can further include determining a duty cycle of the transient electrical signal using the waveform data. The method can further include determining a period “P” of the transient signal, generating a beam of charged particles using a charged particle source, and operating a beam blanker using a periodic pulse signal to pulse the beam of charged particles. The periodic pulse signal can have a period deviating from an integer multiple of P.

In some embodiments, the detector data can be generated using a scanning electron microscope in imaging mode. The detector data can include an image of a surface of the sample including contrast information describing the waveform. The image can include two-dimensional image data and the contrast information includes a two-dimensional contrast pattern. Generating the waveform data can include sampling a one-dimensional vector of image data from the detector data along a direction normal to the contrast pattern.

In some embodiments, the detector data are generated using a scanning electron microscope in spot mode. The detector data can include a detector signal of amplitude against time for a position on a surface of the sample. The position can be a first position on the surface of the sample, the detector data can be first detector data, the period of time can be a first period of time, the multiple can be a first multiple, and the waveform data can be first waveform data. The method can further include directing the pulsed beam of charged particles toward a second position on the surface of the sample, generating second detector data over a second period of time corresponding to a second multiple of the pulse period, and generating second waveform data for the second position. Generating the waveform data can include sampling a segment from the detector signal. The segment can describe temporal dynamics of the transient electrical signal.

In some embodiments, the method further includes generating a trigger signal using the transient electrical signal. The trigger signal can have a trigger period about equal to a least common multiple of a period, P, of the transient electrical signal and the pulse period. The method can further include segmenting the waveform data into one or more blocks of segmented waveform data, a duration of a block being based at least in part on the trigger period. A start time and an end time of the block can be based at least in part on the trigger signal. The method can further include generating visualization data using the one or more blocks of segmented waveform data. The visualization data can be configured to modify a display of an electronic device to present the waveform data as a standing waveform. The method can also further include modifying the display using the visualization data.

In some embodiments, the sample includes an integrated circuit. The charged particles can be directed at a region of the integrated circuit including the conductive feature.

In a second aspect, a system includes a charged particle microscope. The system can include a computing device, operably coupled with the charged particle microscope. The system can also include one or more non-transitory, machine-readable storage media, operably coupled with the computing device, storing executable instructions that, when executed, cause the system to perform operations of the preceding aspects.

In some embodiments, the scanning electron microscope can operate in spot mode. The detector data can include a detector signal of amplitude against time for a given position on a surface of the sample. The position is a first position on the surface of the sample, the detector data are first detector data, the period of time is a first period of time, the multiple is a first multiple, and the waveform data are first waveform data. The operations can further include referencing a set of positions on the DUT, directing the pulsed beam of charged particles toward a second position on the surface of the sample, the second position being a member of the set, generating second detector data over a second period of time corresponding to a second multiple of the pulse period, and generating second waveform data for the second position.

The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims.

### BRIEF DESCRIPTION OF THE SEVERAL VIEWS OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example integrated circuit testing system, in accordance with some embodiments of the present disclosure.

FIG. 2 is a block flow diagram illustrating an example process for generating a difference image of a device under test, in accordance with some embodiments of the present disclosure.

FIG. 3 is a schematic diagram illustrating an example image processing method for generating a difference image, in accordance with some embodiments of the present disclosure.

FIGS. 4A-4G are schematic diagrams illustrating example integrated circuit testing data, including voltage data and difference images, in accordance with some embodiments of the present disclosure.

FIG. 5 is a schematic diagram illustrating example average difference data as a function of differential phase difference, in accordance with some embodiments of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While illustrative embodiments have been illustrated and described, it will be appreciated that various changes can be made therein without departing from the spirit and scope of the disclosure. In the forthcoming paragraphs, embodiments of an analytical instrument system, components, and methods for imaging waveforms using voltage contrast are described. Embodiments of the present disclosure focus on integrated circuit characterization and failure analysis in the interest of simplicity of description. Embodiments are not limited to such instruments, but rather are contemplated for analytical instrument systems configured for electrical signal measurement, which can be measured by techniques including secondary electron detection, and analysis using down-sampling.

Integrated circuit testing involves measurement of individual transistors or groups of transistors of a semiconductor wafer or wafer section (e.g., a diced wafer), termed a “device under test” or DUT. Testing typically includes applying one or more voltage signals to integrated circuit components of the DUT, while measuring a response of the DUT to the signals. Over the course of the test, signals can be varied to simulate off-spec or other challenging conditions, as an approach to stress-testing the DUT, with the goal of eliciting a failure of the DUT while generating measurement data. The measurement data, in turn, can be used to better understand performance characteristics of the DUT, including whether the wafer from which the DUT was taken satisfies one or more quality standards.

A typical IC testing regime includes applying a periodic signal (e.g., a clock signal) to a circuit and monitoring the behavior of the circuit as its operating voltage is varied about a nominal value. That the power consumption of electrical circuitry can decrease as the operating voltage decreases, which can be advantageous for low-power applications such as mobile computing, but circuit performance also decreases below a nominal operating voltage. Below a threshold operating voltage, the circuit can cease to operate. An illustrative example is found in the propagation of a clock signal through a circuit. At nominal operating voltage, the circuit can propagate the clock signal through the circuit at a 50% duty cycle, corresponding to a clock signal that is logic high, or “on,” 50% of the time. As the operating voltage deviates from a nominal voltage, the duty cycle of the clock signal can also deviate from the target of 50%. Techniques for detecting such periodic clock signals independent of the clock's duty cycle offer the advantage of a redundancy and contactless measurement that have relatively less influence on the measured system than a direct measurement technique (e.g., probe circuits).

Measurements of output signals are complicated by several factors. For example, DUT test pattern signals can include frequencies on the order of GHz (1×10⁹ Hz). At such frequencies, signal-to-noise can be impaired by limitations of measurement devices and sampling techniques. Similarly, output signals at frequencies on the order of GHz are typically difficult to interpret visually. Imaging techniques that already suffer from relatively low signal-to-noise detectability for a nominal 50% duty cycle can fail to detect clock signals entirely as the duty cycle trends to 0 or 100% during an IC test. There is a need, therefore, for techniques that permit sampling of internal and output signals from a DUT during testing, in a fashion that is intuitive for visual inspection, for example, during troubleshooting, while also protecting IC components from degradation and that improve signal-to-noise as duty cycle deviates from nominal conditions during an IC test.

To that end, embodiments of the present disclosure include systems, methods, algorithms, and non-transitory media storing machine-readable instructions for generating waveform data describing electrical activity of an integrated circuit component. In an illustrative example, a method can include directing a beam of charged particles toward a sample. The beam can be a pulsed beam. The sample can include a conductive feature to which a transient electrical signal can be applied. The pulsed beam of charged particles is characterized by a pulse period measured in units of time. The method can include generating detector data over a period of time corresponding to a multiple of the pulse period, the detector data being generated based at least in part on interactions between the charged particles and the sample. The method can also include generating waveform data describing the transient electrical signal using the detector data.

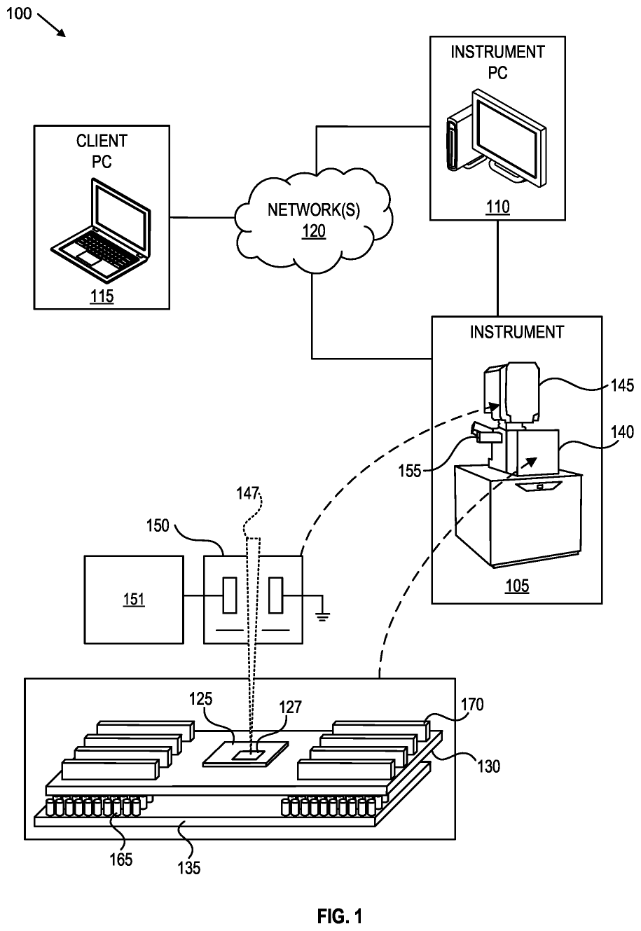

FIG. 1 is a schematic diagram illustrating an example integrated circuit (IC) testing system 100, in accordance with some embodiments of the present disclosure. The example system 100 includes an instrument 105, an instrument computing device (IPC) 110, and a client computing device 115, operably intercoupled via one or more networks 120. The example system 100 is configured to interrogate an IC device, termed a device under test (DUT) 125 using a test assembly 130 electronically coupled with components of the DUT 125 via a controller, also referred to as a test rig 135. Through application of time-varying electronic signals to components of the DUT 125, termed a “test loop,” performance characteristics of circuit components of the DUT 125 can be derived as part of quality control and failure analysis techniques for ICs fabricated according to a given IC design.

The instrument 105 includes a test section 140 in which the test assembly 130 is disposed, including the DUT 125 as well as the electronic components to drive the test loop (e.g., the test rig 135), vacuum components to isolate the DUT 125 from atmosphere, and thermal management systems to remove heat from the DUT 125 during testing. Coupled with the test section 140 is a charged particle column 145. The charged particle column 145 can be an ion beam (e.g., focused ion beam (FIB)) column or an electron beam column (e.g., as part of a scanning electron microscope). In some embodiments, the instrument 105 includes a FIB column and an electron beam column with one of the charged particle sources being coupled with the test section 140 at an angle relative to the charged particle column 145.

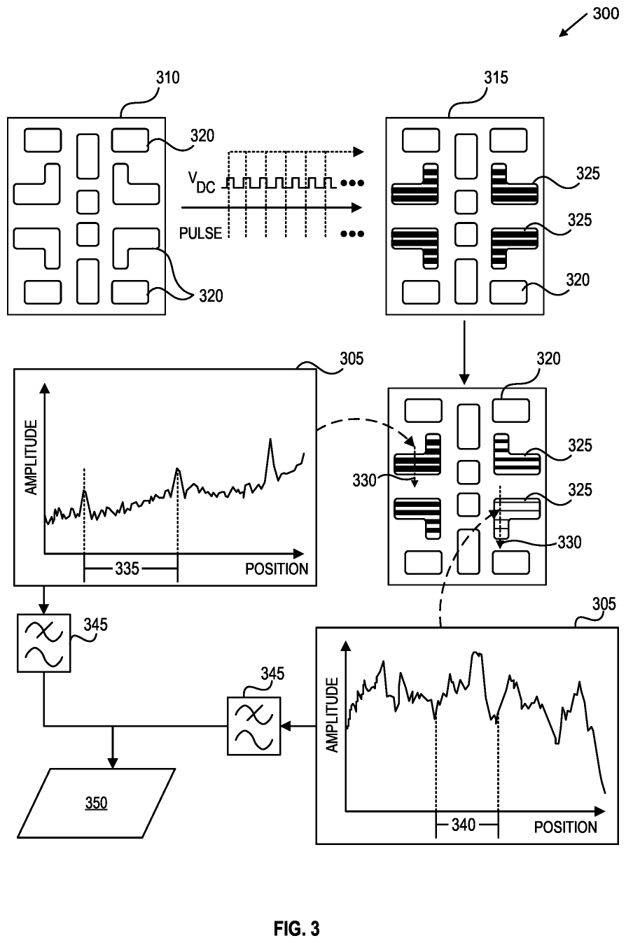

The charged particle column 145 can generate a beam of charged particles 147 and can focus the beam of charged particles 147 onto a region 127 of the DUT 125. The region 127 can include one or more conductive features, as described in more detail in reference to FIG. 3, that can be electrically active and inactive in accordance with one or more transient electrical signals applied to the DUT, also referred to as test pattern(s), test signal(s), test loop(s), or the like. The interaction of the beam of charged particles 147 with the DUT 125 gives rise to one or more detectable signals, which can be received by one or more detectors 155 operably coupled with the test section 140 and configured to generate detector data based at least in part on measurement of the signal(s). In an illustrative example, the detector(s) 155 can include secondary electron detectors, backscattered electron detectors, photon detectors, imaging sensors (e.g., CCDs) or the like. In contrast to a typical scanning electron microscope (SEM), the test section 140 can omit sample manipulation tools, such as an interlock, sample stage, and the like, at least in part because the DUT 125 can be removably coupled with the test assembly 130, which can be disposed on a stage, a cradle, or other retention assembly that provides electronic and thermal coupling with the test section 140 (e.g., coupled with the test rig 135). The beam of charged particles 147 can be directed toward the DUT 125 using various operational modes, including but not limited to imaging mode, line scan mode, spot mode, and/or pulsed mode.

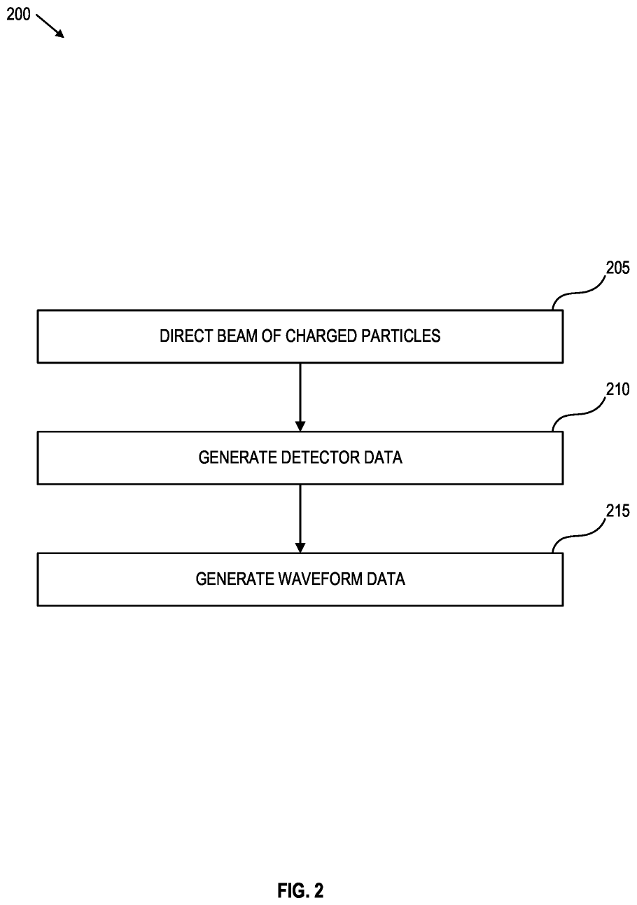

To that end, the charged particle column 145 can include a beam blanker 150, disposed in the column and configured to apply an electric field and/or a magnetic field across the path of the beam of charged particles 147. For example, control electronics 151, operably coupled with the beam blanker 150, can apply a time-variant voltage to an electrode of the beam blanker 150, such that an electric field can reversibly deflect the beam of charged particles 147 into a beam blocker. The operation of the beam blanker can permit the charged particle column 145 to direct pulses of charged particles toward the DUT 125, as described in more detail in reference to FIGS. 2-5. In some embodiments, a pulse includes as few as 1 charged particle to about 1000 charged particles, including physically meaningful fractions of the quoted range and sub-ranges thereof. For example, a pulse can include 3 charged particles, 5 charged particles, 10 charged particles, 15 charged particles, or the like. In some embodiments, a pulse can extend over multiple cycles of a test signal, such that the techniques of the present disclosure can include sampling from multiple points in a set of detector data corresponding to a relatively long period of time, relative to the period of the test signal.

In some embodiments, the test assembly 130 is electronically coupled with components of the test section 140 via couplings 165, by which one or more test cards 170 can be driven. The test cards 170 can encode test loop protocols and can interface with the DUT 125 to input and output signals from the DUT 125 and to relay signals to other constituent elements of example system 100 (e.g., client PC 115 and/or IPC 110).

The computing devices 110 and 115 can be general-purpose machines (e.g., laptops, tablets, smartphones, servers, or the like) that are configured to operate or otherwise interact with the instrument 105. The instrument 105, in turn, can include electronic components that form part of a special-purpose computing device, including control circuitry configured to drive the test loop, operate the test assembly 130, control the electron beam column 145, and operate the vacuum systems and thermal management systems. In an illustrative example, the test assembly 130 can be driven by a chip tester that runs independently from the instrument 105. The operation of the test assembly 130 can be coordinated with that of the instrument 105. For example, a chip tester can generate a trigger signal at the beginning of each test loop that is communicated to instrument 105. The instrument 105, in turn, can respond to the trigger signal at least in part by probing for a signal at a given position in the DUT. In another example, dedicated control electronics can be provided with the instrument 105 to coordinate operations of the instrument 105, such as those of the detector 155 and/or blanker 150, with the test assembly 130. The IPC 110 can be a machine provided with software configured to interface with the instrument 105 and to permit a user of the instrument 105 to conduct a test of the DUT 125. Similarly, the client pc 115 can be configured to control one or more systems of the instrument 105 (e.g., via the IPC 110 and/or by interfacing with the instrument 105 over the network(s) 120) to conduct a test of the DUT 125.

In some embodiments, the instrument 105, the IPC 110, and/or the client PC 115 are in separate physical locations and are coupled via the network(s) 120 and/or by other means, such as direct connection or by wireless connection (e.g., near-field radio). The network(s) 120 can include public networks (e.g., the internet) and/or private networks (e.g., intranet or local area networks). In some embodiments, the IPC 110 and/or the client PC 115 is/are configured to operate the instrument autonomously (e.g., without human intervention) or semi-autonomously (e.g., with limited human intervention, such as initiating a test, identifying a sample, and/or confirming an automated analytical result). In this way, the example system 100 can be configured to operate with human control and/or autonomously, as part of a scalable IC characterization system for automated testing of ICs.

The example system 100 can include additional and/or alternative components than those illustrated. For example, the instrument 105 can be operably coupled with one or more external components, such as signal generators, data acquisition systems, power supply systems, thermal management, or the like. Such components can be housed in cabinets, for example, that are physically separate from the instrument 105, but can be operably coupled with the charged particle column 145, the test section 140, the detectors 155, etc., by electrical and/or fluid-handling connections.

FIG. 2 is a block flow diagram illustrating an example process 200 for generating waveform data for a device under test (DUT), in accordance with some embodiments of the present disclosure. One or more operations of the example process 200 can be executed by a computer system in communication with additional systems including, but not limited to, characterization systems, network infrastructure, databases, and user interface devices. In some embodiments, at least a subset of the operations described in reference to FIG. 2 are performed automatically (e.g., without human involvement) or pseudo-automatically (e.g., with human initiation or limited human intervention). In an illustrative example, operations for applying a test signal, directing the pulse(s) of charged particles toward the DUT (e.g., DUT 125 of FIG. 1), and generating detector data can be executed automatically, with the system (e.g., example system 100 of FIG. 1) being configured to generate visualization data showing one or more forms of waveform data for interpretation by a human user (example shown in FIGS. 3-5).

While example process 200 is described as a sequence of operations, it is understood that at least some of the operations can be omitted, repeated, parallelized, combined and/or reordered. In some embodiments, additional operations precede and/or follow the operations of example process 200 that are omitted for clarity of explanation, for example, operations for calibration of the electron source, alignment and aberration correction of the beam of charged particles, introducing a DUT sample into the vacuum system, calibrating the system, or the like. In another example, a test pattern of time-variant voltage signals are applied to integrated circuit components, as part of determining one or more failure modes of the DUT. In reference to example process 200, the operations of the instrument can be coordinated with those of the test assembly (e.g., test assembly 130 of FIG. 1), as part of generating waveform data describing electrical activity of IC components of the DUT, from which duty cycle information and other information can be derived.

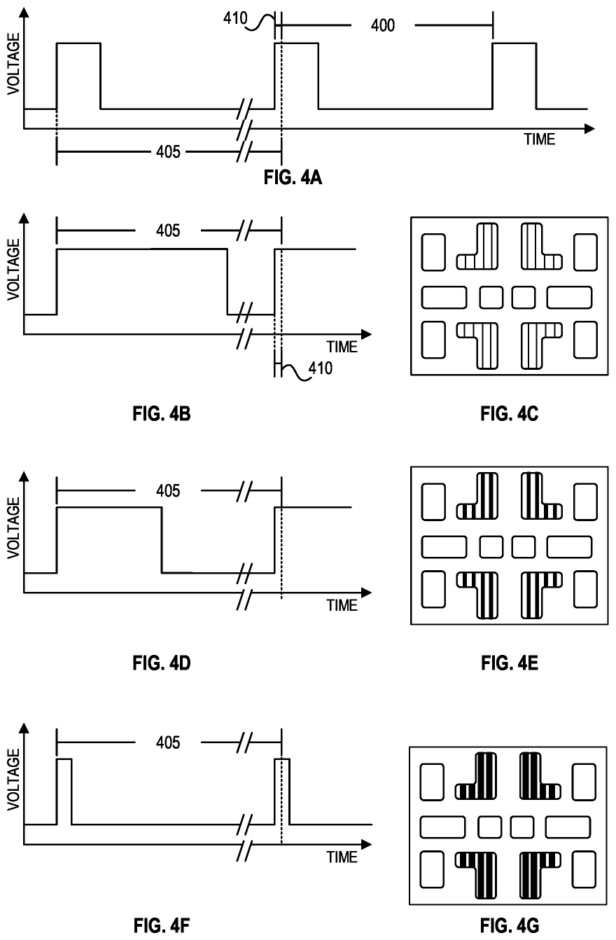

At operation 205, example process 200 includes directing a beam of charged particles toward the DUT (e.g., DUT 125 of FIG. 1). The beam can be pulsed. In some embodiments, the pulses of charged particles can be generated at least in part using a focused beam of charged particles (e.g., ions, electrons) that is intermittently redirected and/or blocked in a beam blanker (e.g., blanker 150 of FIG. 1), although other techniques are possible. Operation 205 can be coordinated with a test signal, as described in more detail in reference to FIGS. 3-4G, such that the at least some of the pulses of charged particles are incident on a region of the DUT (e.g., the region 127 of FIG. 1) at a time that at least a portion of the DUT is active, also referred to as being in an “on” state, while other pulses are incident on the region at a time that the portion of the DUT is inactive, referred to as being in an “off” state.

In some embodiments, operation 205 can include operating the charged particle source in a mode referred to as “CW” or continuous wave, where the beam of charged particles is emitted continuously for a period of time long enough to extend over multiple cycles of the test signal. In CW operation, the detector data can be sampled at times corresponding to the pulse period. In such cases, sampling error can occur where the clock signal has a higher frequency than the frequency cutoff of the secondary-electron detector. Where clock signals are typically hundreds of MHz, detector bandwidth can be about 5 MHz for some typical secondary electron detectors. For this reason, a secondary electron detector with a bandwidth on the order of 100 MHz can be used to generate difference data directly by sampling the detector data and applying difference operations to the sampled data.

In this way, one or more detectors (e.g., the detector(s) 155 of FIG. 1) can generate detector data based at least in part on interactions between the charged particles of the pulsed beam and the DUT, at operation 210. In some embodiments, detector data includes secondary electron detector data, which can be generated by collecting secondary electrons that are reemitted from the surface of the DUT in response to the pulse of charged particles (e.g., using an Everhart-Thornley-type detector). Without being bound to a particular physical mechanism, the secondary electron remission probability can be higher in a region at low electrical potential, and lower in a region of higher electrical potential, such that detector data describing an active region of the DUT can appear relatively bright or dark in detector data. In the case of an electron image, the relative brightness can appear as a lighter coloration (e.g., a bright or saturated region of the image), while for a spectrum, line scan, or spot signal, the relative brightness can correspond to a higher average signal amplitude (e.g., as a function of time or position). In this way, the amplitude of the detector signal (e.g., in units of voltage) can be correlated to the voltage of the region of the DUT (e.g., a voltage at a gate in a transistor). In terms of “on” and “off” states, a test pattern can include a periodic or time-variant signal with periods of relative high voltage and relative low voltage, where the high voltage corresponds to the “on” state and the low voltage corresponds to the “off” state.

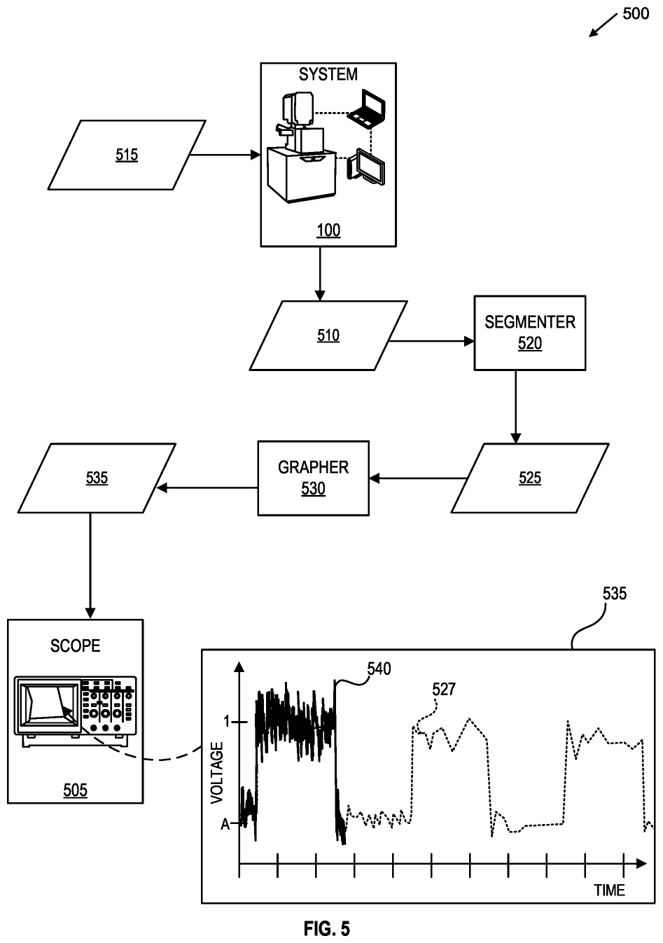

In some embodiments, operations 205 and 210 are repeated in multiple iterations, for example, as part of spatially scanning the beam of charged particles in multiple pulses over at least part of the surface of the DUT. The iterations can be coordinated with the test pattern, such that a pulse period, describing a period of time between repeated iterations of operations 205 and 210, deviates from a period, P, of the test pattern by an increment, dP, of time. In this way, an interference effect can be induced between the test pattern and the detector data, such that the detector data generated in multiple iterations of operation 210 can be used to generate down-sampled waveform data describing the test pattern. As described in more detail in reference to FIGS. 3-4G, the interference effect can result in detector data that, when processed as described in more detail in reference to FIG. 3 and FIG. 5, can be used to extract time-domain information about the test pattern and/or to visualize the waveform applied to a given IC element or elements of the DUT (e.g., a conductive feature, a dielectric feature, etc.). Line-scan or spot mode data can be used for an analogous purpose, for example, spatially scanning a pulsed beam across a linear region of the DUT and generating one-dimensional detector data showing signal amplitude as a function of beam position. Spot-mode, as part of operation(s) 205, can be informed by a mapping of locations of interest on the DUT, for example, referencing a hot-spot simulation analysis of the DUT. In this way, average electron (or ion) dose can be reduced for the DUT overall, without impairment to the quality of waveform data produced by the example process 200. To that end, DUT design information can be used to define a set of locations in a region of interest on the DUT at which waveform data can be generated.

The test loop can include test patterns having frequencies on the order of 1-10 GHz, corresponding to a period on the order of about 1 nsec or less. Physical limitations governing the response time of charged particle microscopy systems can limit the temporal resolution of detector data, such that consecutive iterations of operations 205 and 210 can be separated in time by an offset of about an integer multiple of the period and the increment, dP, such that the detector data generated at consecutive iterations of operation 210 are temporally resolved. In this way, a pulse period, Pₑ, (or sampling period for CW operation) can be defined such that Pₑ≈N*P+dP. For example, where the period of the test pattern, P, is about 3 ns, and the temporal-resolution of the charged particle system and detectors is about 100 ns, the integer multiple, N, can be about 50. In this way, a first iteration of operations 205 and 210 can be executed at an initial time tₒ, a second at about t₁≈N*P+dP≈150 ns+dP, a third at about t2≈2*N*P+2*dP≈300 ns+2*dP, etc. In this way, each data point is resolved in time, and the electron pulses advance in time through the test pattern period P.

The value of the increment, dP, can be based at least in part on the temporal resolution of the beam blanker, and can be on the order of fractions of a nanosecond (e.g., 1×10⁻¹⁰ sec). In this way, each subsequent iteration of operations 205 and 210 can be progressively offset, relative to the test pattern, by an incremented multiple of dP. In effect, the detector data generated at repeated iterations of operation 210 can be understood to sample different points on the test pattern, as illustrated in FIG. 3, from which the waveform at a given position on the DUT can be reconstructed. Further, the interference effect, as described by waveform data generated at operation 215, permits the duty cycle to be derived. Duty cycle can be an important indicator of IC performance, with the duty cycle progressively deviating from specification as the DUT begins to fail. In this way, operation 215 can include determining a duty cycle of an IC component, for example, by sampling the amplitude of the secondary electron signal over a period of time, reconstructing the temporal dynamics of electrical activity of the IC component, and determining the ratio of “on” time to “off” time for the IC component. Advantageously, this sampling technique also reduces the overall dose of charged particles incident on the DUT surface by exposing the surface to flux of charged particles for a fraction of the time over which the test pattern is applied to the IC components of the DUT.

FIG. 3 is a schematic diagram illustrating an example data processing method 300 for generating waveform data 305, in accordance with some embodiments of the present disclosure. Generating the waveform data 305 can include generating an image 315 of a region 310 of a DUT (e.g., DUT 125 of FIG. 1) by scanning a beam of charged particles (e.g., beam of charged particles 147 of FIG. 1) over the region 310, while pulsing the beam, as described in reference to example process 200 of FIG. 2. Where detector data include line-scan or point-mode data, waveform data 305 can be or include spectrum data drawn from detector data. For images, waveform data 305 can be sampled from image data. In this way, image data can be sampled to produce waveform data for multiple positions of the region 310 and/or for multiple different test patterns at different times.

The region 310 includes multiple features 320 that can be integrated circuit components, conductive regions of the surface, or other features. In the active “on” portion of the test pattern, one or more of the features 320 can be intermittently electrically activated in accordance with the test pattern. By generating detector data in pulsed mode, as described in reference to FIG. 2, the image 315 can includes one or more patterned regions 325, compared to those regions corresponding to inactive features 320 that do not manifest such patterns. The patterned regions 325 are shown with the same pattern of dark and white horizontal stripes, referred to as a “barber pole” pattern. It is understood, however, that different patterns can manifest for different active regions, for example, where different test patterns are applied to different components of the DUT, or where different components receive different signal inputs as part of the functioning of the DUT. The patterns illustrated result at least in part from down-sampling the temporal activity (e.g., frequency, duty cycle, etc.) of the DUT, thereby permitting image data to visually represent both the “on” state and the “off” state of at least a subset of the features 320 in a combined image. For given value of an integer multiple, N, and a given value of the increment, dP, the pattern(s) can be measured and up-sampled to reconstruct the waveform observed at the relevant feature 320.

Measuring the pattern, in image data, can include extracting an intensity profile from the image and applying one or more spectral analysis techniques to determine the amplitude of the detector signal as a function of position. As illustrated in FIG. 3, the intensity profile can be extracted by sampling the image data along a ray 330 that is oriented relative to the pattern such that the waveform captures the periodic characteristics of the pattern. In the case of a horizontally-oriented pattern, as shown in FIG. 3, the ray 330 can be oriented substantially vertically. As the orientation of the pattern is based at least in part on the scan pattern of the beam of charged particles that is used to generate the image data, the ray 330 can be oriented in different directions than those shown. Along the direction of the ray 330, the amplitude of the image signal (e.g., measured in counts, voltage, etc.) can be sampled to generate a vector of waveform data 305.

The raw waveform data vector will include noise from the detector data. As such, the example method 300 can include one or more post-processing operations, applied to at least a portion of the waveform data 305, as part of determining temporal characteristics of the activity of the DUT component sampled by the ray 330 and for generating output data 350, such as filtered waveform data. Such characteristics include, but are not limited to, a frequency, a period 335 and 340, and/or a duty cycle. Filters 345, such as bandpass filters or other frequency-based filters, can be used to selectively remove noise from the waveform data 305.

The spectra in FIG. 3, while not to scale, represent real experimental data extracted from a conductive element in a sample under an applied periodic voltage. As shown, temporal dynamic information can be extracted to reconstruct different duty cycles. The period 335 and the period 340 can be equal or can be different. In the illustration, the period 335 and the period 340 are substantially equal, appearing different visually, owing to the different distances over which the respective rays 330 extend. Instead, the duty cycle is different, as described in more detail in reference to FIGS. 4A-4G. Advantageously, the example method 300 is relatively insensitive to the duty cycle of the DUT, at least in part because both the “on” state and the “off” state are sampled to produce the detector data (e.g., the image data), from which a down-sampled waveform can be extracted. In this way, even in cases where the duty cycle deviates from the nominal value, the patterned region(s) 325 can be generated.

FIGS. 4A-4G are schematic diagrams illustrating example integrated circuit testing data, including voltage data and example electron microscope images, in accordance with some embodiments of the present disclosure. FIG. 4A, FIG. 4B, FIG. 4D, and FIG. 4F represent voltage signals corresponding to a test pattern using a square wave signal. FIG. 4C, FIG. 4E, and FIG. 4G represent electron microscope images (e.g., image 315 of FIG. 3) generated in accordance with the example process 200, as described in more detail in reference to FIGS. 2-3.

FIG. 4A is an example test pattern, using a square-wave voltage signal characterized by a period 400. In integrated circuit testing, the period 400 can be on the order of 1-100 nanoseconds, as determined by the IC manufacturer's test protocol. In this way, example process 200 can be coordinated with an arbitrary test pattern. FIG. 4A also illustrates a duty cycle that deviates from 50%. While not to scale, the duty cycle of the example test pattern in FIG. 4A corresponds to a value between 10% and 30%. The techniques of the present disclosure are not limited to this range, however, being relatively insensitive to duty cycle in comparison to conventional techniques.

In each of FIG. 4A, FIG. 4B, FIG. 4D, and FIG. 4F, a sampling period 405 is shown across multiple values of the period 400, as indicated by parallel lines intersecting the temporal, horizontal axis. The sampling period 405 differs from the period by an increment 410 of time, dP, that can be from about 0.00001 nanoseconds to about 1 nanoseconds, including sub-ranges, fractions, and interpolations thereof. The value of dP can be based at least in part on the temporal resolution of a beam blanker of the system with which the example processes of the present disclosures are implemented. For example, where a system has a temporal resolution of 0.0001 nanoseconds on detector data, the down-sampling can be reduced, providing more detailed detector data from which to generate waveform data.

FIG. 4B illustrates a sampling condition during which the sampling period 405 initially coincides with two active “on” states of the DUT, at a value of the duty cycle above 50%. Each period 400 of the test pattern can be factored by the increment 410 to provide the number of sampling points in each full period of the test pattern. The duration of the “on” active state, factored by the increment 410, gives the number of sampling periods 405 that will measure the “on” state. Similarly, the duration of the “off” state, factored by the increment 410, gives the number of sampling periods 405 that measure the “off” state. Similarly, the duty cycle can be determined by measuring the number of points in waveform data that sample the “on” state and the number that sample the “off” state, and finding the ratio of the two. Correlating the spatial distance in the image with time-domain information can be achieved via scan pattern information of the beam (e.g., dwell time and scan rate) used to generate the image data. From this information, the waveform data can be transformed from position to time as the independent variable. In FIG. 4C, a lower duty cycle, closer to 50%, does not affect the quality of detector data and/or image data. Similarly, FIG. 4D illustrates a duty cycle significantly lower than 50%, as an example of the observed portion of the DUT (e.g., region 310 of FIG. 3) approaching failure, for which the sampling technique of the present disclosure produces a pattern in detector data from which waveform data can be extracted that can be processed to reproduce the waveform of the test pattern.

In this way, the processes and techniques of the present disclosure (e.g., example process 200 of FIG. 2) can include operations for reconstructing waveforms of the test patterns used to periodically and/or aperiodically activate IC components of the DUT, thereby allowing the system to monitor changes in duty cycle and other performance characteristics during a test. This approach can be repeated over the course of a test loop, such that waveform data can be generated in a manner that is substantially insensitive to changes in the duty cycle. In some embodiments, the increment 410 can be modified during the course of a test. For example, where the duty cycle is lower or higher than a point at which the “on” state or the “off state is shorter than the increment 410, the increment can be shortened to provide one or more sampling points during the respective state.

FIG. 5 is a block flow diagram illustrating an example data processing technique 500 for generating visualization data of a test pattern, in accordance with some embodiments of the present disclosure. The example technique 500 can be implemented automatically (e.g., without human intervention), pseudo-automatically (e.g., with limited human intervention), and/or manually (e.g., with human specification of process parameters, initiation, termination, etc.). The example technique 500 can form a part of the example process 200 of FIG. 2, such that the waveform data generated can be outputted and/or visualized by a user of a tester system (e.g., system 100 of FIG. 1). In FIG. 5, the example technique 500 is shown generating visualization data for presentation on a digital oscilloscope 505, but similar data can be generated as part of the example technique 500 for presentation of waveform data on other devices (e.g., client PC 115 of FIG. 1, instrument PC 110 of FIG. 1, etc.).

The example technique 500 can include techniques for phase-locking the waveform data such that the waveform data can be visualized as a standing wave. To that end, the example technique can include generating a trigger signal 510 based at least in part on a transient electrical signal 515, such as the test pattern provided to the DUT. The trigger signal 510 can have a trigger period about equal to a least common multiple of the period, P, of the transient electrical signal 515 (e.g., period 400 of FIG. 4) and a pulse period provided to pulse the beam of charged particles (e.g., sampling period 405 of FIG. 4). The trigger period, therefore can also be a smaller number, as defined by the least common multiple of the two periods.

The trigger signal 510 can be used to process the detector data and/or the waveform data to segment (at segmenter block 520) the waveform data into one or more blocks of segmented waveform data 525. Segmenting can be based at least in part on a duration of a block being defined at least in part by the trigger period. A start time and an end time can be based at least in part on the trigger signal. For example, the trigger signal can include timing information, such as a start trigger and an end trigger. In another example, the trigger signal can be generated concurrently with the visualization data, such that segmentation is initiated with the trigger signal (e.g., as a result of a selection of a menu option by a user to present the visualization data on the scope 505). In some embodiments, example technique 500 can include filtering and/or smoothing the segmented waveform data 525, providing smoothed data 527, such that the noise in the visualization data 535 is reduced, thereby easing visual inspection and reducing variability in quantification.

The example technique can also include generating visualization data 535 using the one or more blocks of segmented waveform data 525, at grapher block 530. The visualization data 525 being configured to modify a display of the scope 505 to present the waveform data as a standing waveform 540. In this way, the example technique can include modifying the display of the scope using the visualization data to visualize the waveform data 535 generated as part of example processes of the present disclosure (e.g., example process 200, example method 300, etc.). Advantageously, visualizing a standing wave permits a user of the scope 505 to visually assess the temporal dynamics of the waveform concurrently with the DUT being tested. For example, the duty-cycle can be visually assessed and quantified during a test, rather than in post-test analysis.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on integrated circuit testing systems, and scanning electron microscope systems in particular, these are meant as non-limiting, illustrative embodiments.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For numerical values, such as diameters, lengths, widths, or the like, the term “about” can be understood to describe a deviation from the stated value of up to ±10%, or other value as is typical in a relevant field of art. For example, a dimension of “about 10 mm” can describe a dimension from 9 mm to 11 mm, and a time on the order of 1 ns can denote a time from 0.3 ns to 3 ns.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A computer-implemented method, comprising:
directing a pulsed beam of charged particles toward a sample, the sample comprising a conductive feature to which a transient electrical signal is applied, wherein the pulsed beam of charged particles is characterized by a pulse period measured in units of time;
generating detector data over a period of time corresponding to a multiple of the pulse period, the detector data being generated based at least in part on interactions between the charged particles and the sample; and
generating waveform data describing the transient electrical signal using the detector data.

2. The computer-implemented method of claim 1, wherein the transient signal is a periodic electrical signal, wherein a value “P” is a period of the transient signal, measured in units of time, and wherein the pulse period differs from an integer multiple of P, N*P, by an increment, dP.

3. The computer-implemented method of claim 1, further comprising determining a duty cycle of the transient electrical signal using the waveform data.

4. The computer-implemented method of claim 1, further comprising:
determining a period “P” of the transient signal;
generating a beam of charged particles using a charged particle source; and
operating a beam blanker using a periodic pulse signal to pulse the beam of charged particles, the periodic pulse signal having a period deviating from an integer multiple of P.

5. The computer-implemented method of claim 1, wherein the detector data are generated using a scanning electron microscope in imaging mode, and wherein the detector data comprise an image of a surface of the sample including contrast information describing the waveform.

6. The computer-implemented method of claim 5, wherein the image comprises two-dimensional image data and the contrast information includes a two-dimensional contrast pattern, and wherein generating the waveform data comprises sampling a one-dimensional vector of image data from the detector data along a direction normal to the contrast pattern.

7. The computer-implemented method of claim 1, wherein the detector data are generated using a scanning electron microscope in spot mode, wherein the detector data comprise a detector signal of amplitude against time for a position on a surface of the sample.

8. The computer-implemented method of claim 7, wherein the position is a first position on the surface of the sample, the detector data are first detector data, the period of time is a first period of time, the multiple is a first multiple, and the waveform data are first waveform data, the method further comprising:
directing the pulsed beam of charged particles toward a second position on the surface of the sample;
generating second detector data over a second period of time corresponding to a second multiple of the pulse period; and
generating second waveform data for the second position.

9. The computer-implemented method of claim 7, wherein generating the waveform data comprises sampling a segment from the detector signal, the segment describing temporal dynamics of the transient electrical signal.

10. The computer-implemented method of claim 1, further comprising:
generating a trigger signal using the transient electrical signal, the trigger signal having a trigger period about equal to a least common multiple of a period, P, of the transient electrical signal and the pulse period.

11. The computer-implemented method of claim 10, further comprising:
segmenting the waveform data into one or more blocks of segmented waveform data, a duration of a block being based at least in part on the trigger period and a start time and an end time being based at least in part on the trigger signal;
generating visualization data using the one or more blocks of segmented waveform data, the visualization data being configured to modify a display of an electronic device to present the waveform data as a standing waveform; and
modifying the display using the visualization data.

12. The computer-implemented method of claim 1, wherein the sample comprises an integrated circuit, and wherein the charged particles are directed at a region of the integrated circuit including the conductive feature.

13. A system, comprising:
a charged particle microscope;
a computing device, operably coupled with the charged particle microscope; and
one or more non-transitory, machine-readable storage media, operably coupled with the computing device, storing executable instructions that, when executed, cause the system to perform operations comprising:
directing a pulsed beam of charged particles toward a sample, the sample comprising a conductive feature to which a transient electrical signal is applied, wherein the pulsed beam of charged particles is characterized by a pulse period measured in units of time;
generating detector data over a period of time corresponding to a multiple of the pulse period, the detector data being generated based at least in part on interactions between the charged particles and the sample; and
generating waveform data describing the transient electrical signal using the detector data.

14. The system of claim 13, wherein the transient signal is a periodic electrical signal, wherein a value “P” is a period of the transient signal, measured in units of time, and wherein the pulse period differs from an integer multiple of P, N*P, by an increment, dP.

15. The system of claim 13, further comprising determining a duty cycle of the transient electrical signal using the waveform data.

16. The system of claim 13, further comprising:
determining a period “P” of the transient signal;
generating a beam of charged particles using a charged particle source; and
operating a beam blanker using a periodic pulse signal to pulse the beam of charged particles, the periodic pulse signal having a period deviating from an integer multiple of P.

17. The system of claim 13, wherein the detector data are generated using a scanning electron microscope in spot mode, wherein the detector data comprise a detector signal of amplitude against time for a position on a surface of the sample.

18. The system of claim 17, wherein the position is a first position on the surface of the sample, the detector data are first detector data, the period of time is a first period of time, the multiple is a first multiple, and the waveform data are first waveform data, the operations further comprising:
referencing a set of positions on the DUT;
directing the pulsed beam of charged particles toward a second position on the surface of the sample, the second position being a member of the set;
generating second detector data over a second period of time corresponding to a second multiple of the pulse period; and
generating second waveform data for the second position.

19. The system of claim 13, wherein generating the waveform data comprises sampling a segment from the detector data, the segment describing temporal dynamics of the transient electrical signal.

20. The system of claim 13, wherein the sample comprises an integrated circuit, and wherein the charged particles are directed at a region of the integrated circuit including the conductive feature.
